(19) United States
(12) Patent Application Publication
(10) Pub. No.: US 2011/0177679 A1
(43) Pub. Date: Jul. 21, 2011

(54) METHOD FOR MANUFACTURING SEMICONDUCTOR DEVICE

(75) Inventors: Akihito Ohno, Tokyo (JP); Kazushige Kawasaki, Tokyo (JP)

(73) Assignee: MITSUBISHI ELECTRIC CORPORATION, Tokyo (JP)

(21) Appl. No.: 12/889,474

(22) Filed: Sep. 24, 2010

(30) Foreign Application Priority Data
Jan. 20, 2010 (JP) 2010-010056

(51) Int. Cl. H01L 21/20

(52) U.S. Cl. 438/478; 257/E21.09

(57) ABSTRACT

A method for manufacturing a semiconductor device includes preparing a substrate having a low-dislocation region and a high-dislocation region having a higher dislocation density than dislocation density of the low-dislocation region; forming an insulating film on the low-dislocation region surrounding the high-dislocation region but not covering the high-dislocation region; and forming a nitride-based semiconductor layer on the substrate, after forming the insulating film.

### BACKGROUND OF THE INVENTION

1. Field of the Invention

The present invention relates to a method for manufacturing a semiconductor device provided with a nitride semiconductor layer formed on a substrate having a low-dislocation region and a high-dislocation region; and specifically, relates to a method for manufacturing a semiconductor device that can improve the surface flatness of the nitride semiconductor layer.

2. Background Art

When a nitride semiconductor layer is formed on a substrate having a low-dislocation region and a high-dislocation region, abnormal growth generated on the high-dislocation region may be transmitted to the low-dislocation region causing the degradation of the flatness of the nitride semiconductor layer. To solve such a problem, ,a method for preventing abnormal growth on the high-dislocation region by forming an insulating film so as to cover the high-dislocation region has been proposed (for example, refer to Japanese Patent Application Laid-Open No. 2004-221480).

### SUMMARY OF THE INVENTION

Conventionally, since an insulating film has been formed so as to cover a high-dislocation region, the insulating film has inevitably widened. Therefore, during the growth of the nitride semiconductor layer, materials are diffused from the insulating film, and the nitride semiconductor layer is thickened in the vicinity of the insulating film. As a result, there have been problems wherein the surface flatness of the nitride semiconductor layer is degraded, and the yield of elements is lowered.

In view of the above-described problems, an object of the present invention is to provide a method for manufacturing a semiconductor device that can improve the surface flatness of the nitride semiconductor layer.

According to the present invention, a method for manufacturing a semiconductor device comprises: preparing a substrate having a low-dislocation region and a high-dislocation region having a higher dislocation density than a dislocation density of the low-dislocation region; forming an insulating film on the low-dislocation region so as to surround the high-dislocation region but not to cover the high-dislocation region; and forming a nitride-based semiconductor layer on the substrate after forming the insulating film.

The present invention makes it possible to improve the surface flatness of the nitride semiconductor layer.

Other and further objects, features and advantages of the invention will appear more fully from the following description.

### BRIEF DESCRIPTION OF THE DRAWINGS

FIGS. 1 to 3 are sectional views for illustrating a method for manufacturing a semiconductor device according to an embodiment of the present invention.

FIG. 4 is a top view showing a semiconductor device manufactured using the manufacturing method according to the comparative example.

FIG. 5 is a top view showing a semiconductor device manufactured using the manufacturing method according to the present embodiment.

### DETAILED DESCRIPTION OF THE PREFERRED EMBODIMENTS

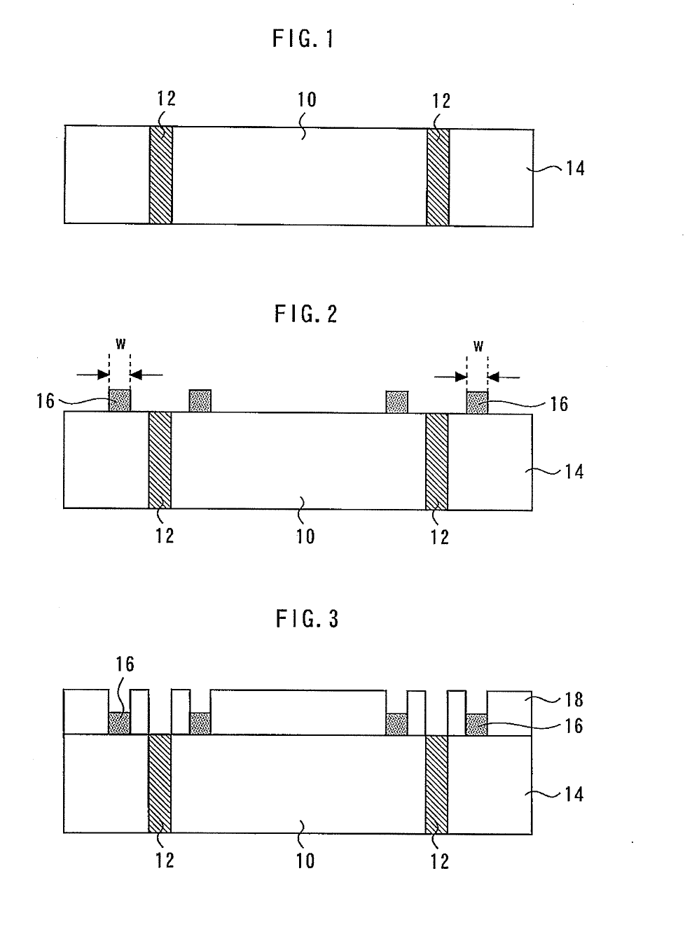

A method for manufacturing a semiconductor device according to an embodiment of the present invention will be described referring to the drawings. FIGS. 1 to 3 are sectional views for illustrating a method for manufacturing a semiconductor device according to an embodiment of the present invention.

First, as shown in FIG. 1, a GaN substrate 14 having a low-dislocation region 10 and a high-dislocation region 12 having a higher dislocation density than the low-dislocation region 10 is prepared. The low-dislocation region 10 has Ga polarity, and the high-dislocation region 12 has N polarity.

Next, as shown in FIG. 2, an insulating film 16 composed of SiO₂ or SiN is formed on the low-dislocation region 10 so as to surround the high-dislocation region 12 but not to cover the high-dislocation region 12. The width w of the insulating film 16 is 10 μm, and the thickness thereof is 1000 Å. The insulating film 16 is formed using vapor deposition, sputtering, CVD or the like. Here, the insulating film 16 is formed 10 μm apart from the outer edge of the high-dislocation region 12.

Next, as shown in FIG. 3, a nitride semiconductor layer 18 composed of AlₓIn_{y}Ga_{(1-x-y)}N (0≦x≦1, 0≦1) is formed on the GaN substrate 14. At this time, the nitride semiconductor layer 18 is little grown on the high-dislocation region 12 and the insulating film 16 having reverse polarity from the polarity of the low-dislocation region 10. However, the nitride semiconductor layer 18 is formed on the GaN substrate 14 between the high-dislocation region 12 and the insulating film 16.

In addition, light-emitting elements (not shown) are periodically formed on the nitride semiconductor layer 18 formed on the low-dislocation region 10. Specifically, the nitride semiconductor layer 18 is constituted of an n-type GaN layer of a thickness of 1 μm, an n-type A_{0.07}Ga_{0.93}N of a thickness of 1 μm, an n-type GaN layer of a thickness of 100 nm, an active layer, an p-type Al_{0.2}Ga_{0.8}N layer of a thickness of 20 nm, a p-type GaN layer of a thickness of 10 nm, a p-type Al_{0.07}Ga_{0.93}N of a thickness of 400 nm, and a p-type GaN layer of a thickness of 100 nm sequentially laminated from the GaN substrate 14. The active layer is a multiple quantum well wherein 3 cycles of In_{0.02}Ga_{0.9}N layers each having a thickness of 3.5 nm and In_{0.02}Ga_{0.98}N layers each having a thickness of 7 nm are laminated.

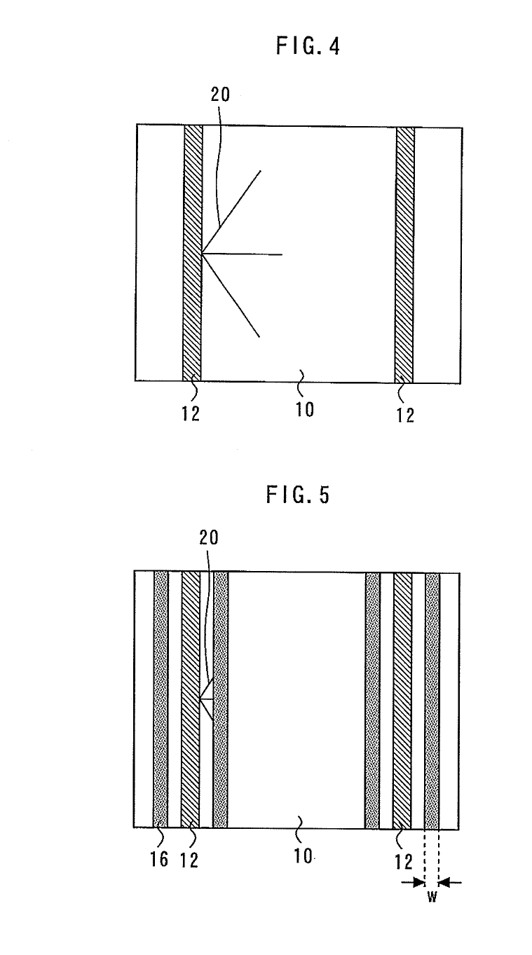

The effects of the present embodiment will be described comparing with a comparative example. FIG. 4 is a top view showing a semiconductor device manufactured using the manufacturing method according to the comparative example. In FIG. 4, the nitride semiconductor layer 18 is seen through. In the comparative example, since no insulating film 16 is formed, abnormal growth 20 generated on the high-dislocation region 12 is transmitted into the low-dislocation region 10.

FIG. 5 is a top view showing a semiconductor device manufactured using the manufacturing method according to the present embodiment. In the present embodiment, since the insulating film 16 is formed on the low-dislocation region 10 so as to surround the high-dislocation region 12, the transmitting of abnormal growth 20 generated on the high-dislocation region 12 into the low-dislocation region 10 can be prevented.

Also, since the high-dislocation region 12 is not covered by the insulating film 16, the width w of the insulating film 16 can be reduced. Therefore, the thickening of the nitride semiconductor layer 18 in the vicinity of the insulating film 16 due to the diffusion of materials can be prevented. As a result, the surface flatness of the nitride semiconductor layer 18 can be improved, and the yield of the semiconductor devices can be elevated. Specifically, in order to improve the surface flatness, the width w of the insulating film 16 is made to be not more than 30 μm. However, in order to prevent the transmitting of abnormal growth, the width w of the insulating film 16 must be not less than 1 μm.

Also, the thickness of the insulating film 16 is preferably 500 to 5000 Å. This is because if the insulating film 16 is thinner than 500 Å, the nitride semiconductor layer 18 is laterally grown on the insulating film 16 to cover the insulating film 16; and if the insulating film 16 is thicker than 5000 Å, stress due to the formation of the insulating film 16 is significantly enlarged to warp the substrate. It is further preferable to make the thickness of the insulating film 16 be 1000 to 2000 Å.

Also, the insulating film 16 is preferably composed of SiO₂ or SiN. Thereby, the nitride semiconductor layer 18 is little grown on the insulating film 16. SiO₂ or SiN is stable even at a high temperature of around 1000° C.

In the present embodiment, although the high-dislocation region 12 and the insulating film 16 are stripe-shaped, if the insulating film 16 has the shape to surround the high-dislocation region 12, the high-dislocation region 12 and the insulating film 16 may have the shape other than stripe-shape.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-010056, filed on Jan. 20, 2010 including specification, claims, drawings and summary, on which the Convention priority of the present application is based, are incorporated herein by reference in its entirety.

1. A method for manufacturing a semiconductor device comprising:
preparing a substrate having a low-dislocation region and a high-dislocation region having a higher dislocation density thanes dislocation density of the low-dislocation region;
forming an insulating film on the low-dislocation region surrounding the high-dislocation region but not covering the high-dislocation region; and
forming a nitride-based semiconductor layer on the substrate after forming the insulating film.

2. The method for manufacturing a semiconductor device according to claim 1, wherein width of the insulating film is not more than 30 μm.

3. The method for manufacturing a semiconductor device according to claim 1, wherein the insulating film is one of SiO₂ and SiN.

4. The method for manufacturing a semiconductor device according to claim 1, wherein the substrate is GaN, the low-dislocation region has Ga polarity, and the high-dislocation region has N polarity.
